(19) United States
(12) Patent Application Publication
(10) Pub. No.: US 2008/0041621 A1
(43) Pub. Date: Feb. 21, 2008

(54) CIRCUIT BOARD STRUCTURE AND METHOD FOR FABRICATING THE SAME

(75) Inventors: Shih-Ping HSU, Hsin-chu (TW); Ya-Lun YEN, Hsin-chu (TW)

Correspondence Address: SAWYER LAW GROUP LLP, P O BOX 51418, PALO ALTO, CA, 94303, US

(73) Assignee: PHOENIX PRECISION TECHNOLOGY CORPORATION, Hsin-chu (TW)

(21) Appl. No.: 11/673,543

(22) Filed: Feb. 9, 2007

(30) Foreign Application Priority Data
Feb. 15, 2006 (TW) 095105026

(51) Int. Cl. H05K 1/11; H01R 12/04

(52) U.S. Cl. 174/262; 174/255

(57) ABSTRACT

A circuit board structure and a method for fabricating the same are proposed. A substrate with a first circuit layer formed on at least one surface thereof is provided. A dielectric layer is formed on the surface of the substrate, and a plurality of first and second openings are formed in the dielectric layer, wherein the second openings expose electrical connection pads of the first circuit layer. A metal layer is formed on the surface of the dielectric layer and in the first and second openings. By removing the metal layer on the surface of the dielectric layer, a second circuit layer is formed in the second openings, and a conductive structure is formed in the second openings for electrical connection with the first circuit layer. The present invention improves the bonding strength between the circuit layer and the dielectric layer, and the ability of fabricating fine circuits.

### CROSS-REFERENCE TO RELATED APPLICATIONS

Under 35 USC 119(e), this application claims foreign priority to Taiwan application No. 095105026, filed Feb. 15, 2006, all of which is incorporated herein by reference.

### FIELD OF THE INVENTION

The present invention relates to circuit board structures and methods for fabricating the same, and more particularly, to a build-up circuit board with fine circuits and a method for fabricating the build-up circuit board.

### BACKGROUND OF THE INVENTION

In response to the booming electronics industry, electronic products have been developed with multi-functionality and high performance. Further with a view to fabricating highly integrated and miniaturized semiconductor packages and carrying more active components and circuits, a substrate serving as a carrier in a semiconductor package has been made in the form from a double-layer circuit board to a multi-layer circuit board. The multi-layer circuit board employs an interlayer connection technique to increase a circuit layout area on the substrate with definite space, such that more circuits and electronic components can be accommodated on the substrate so as to fulfill the high-integration and low-profile requirements for the semiconductor package.

For use with a high-performance chip incorporated in a semiconductor package having a large number of I/O (input/output) connections, such as microprocessor, chipset, graphic chip and application specific integrated circuit (ASIC), it is necessary to improve the functions, such as impedance control, bandwidth, and chip signal transmission, of the substrate for the semiconductor package. Accordingly, the substrate has been developed to form fine circuits and small vias therein to be applicable to the highly integrated, high-performance and miniaturized semiconductor package. Conventionally, the line width of the substrate has been decreased from 100 μm to smaller than 30 μm, and the line width, space and aspect ratio are continuously being reduced. Here, “line space” refers to space between adjacent lines or circuits.

To improve circuit layout density of the substrate for the semiconductor package, there has been provided a circuit build-up technology, which allows a plurality of dielectric layers and circuit layers to be stacked on a core circuit board, with conductive vias being formed in the dielectric layers to electrically connect different circuit layers. Therefore, the circuit build-up process plays an important in the circuit density of the substrate. Currently, build-up circuits are mostly fabricated by a semi-additive process (SAP) and a pattern plating method.

The pattern plating method involves forming at least one through hole in a resin coated copper (RCC) core board so as to allow copper foils on both sides of the core board to communicate with each other by the through hole. Then, a conductive layer is formed on the copper foils and in the through hole by electroless plating, a patterned resist layer is formed on the conductive layer, and patterned circuit layers are formed on the conductive layer by electroplating. Subsequently, the resist layer is removed and etching is performed to remove the conductive layer covered by the resist layer. As a result, circuits are fabricated on the core board.

The semi-additive process involves forming a dielectric layer on a surface of a circuit board having a circuit layer disposed thereon, and forming at least one opening in the dielectric layer to partially expose the circuit layer. Then, a conductive layer is formed on the dielectric layer by electroless copper plating, allowing the conductive layer to be electrically connected to a portion of the circuit layer. Subsequently, a patterned resist layer is formed on the conductive layer, and an electroplating process is performed to form patterned circuit layers on the conductive layer. Afterwards, the resist layer is removed and etching is performed to remove the conductive layer covered by the resist layer. The above processes for forming dielectric layers and circuit layers are repeated such that a circuit board with multiple circuit layers is fabricated.

However, when fabricating fine circuits by the semi-additive process or the pattern plating method for the multi-layer substrate, due to the small line space of the fine circuits, the bonding strength between the circuit layers and the dielectric layers is not strong enough such that product reliability and quality are compromised. On the other hand, if enhancing the bonding strength between the circuit layers and the dielectric layers, the line width would be undesirably increased, which is not favorable for fabrication of the fine circuits.

Moreover, both the semi-additive process and the pattern plating method involve forming a conductive layer on a dielectric layer disposed on the substrate, forming a resist layer on the conductive layer, forming at least one opening in the resist layer by exposure and development or by laser drilling, and plating a patterned circuit layer in the opening. However, because of the constraints on the exposure and development processes, precision of the laser drilling and the bonding strength of the conductive layer, for example, due to the limits of ultraviolet wavelength, diffraction during exposure makes peripheral portions of photoresist patterns blurred, such that it is not easy to define the line width, reduce the line width and control the line thickness.

### SUMMARY OF THE INVENTION

In view of the above drawbacks of the prior art, a primary objective of the present invention is to provide a circuit board structure and a method for fabricating the same, so as to increase the bonding strength between a circuit layer and a dielectric layer.

Another objective of the present invention is to provide a circuit board structure and a method for fabricating the same, so as to allow the circuit board to be formed with fine circuits.

A further objective of the present invention is to provide a circuit board structure and a method for fabricating the same, so as to effectively control the shape of circuits and enhance the electrical performance of the circuit board.

In order to achieve the above and other objectives, the present invention proposes a method for fabricating a circuit board structure. The method comprises the steps of: providing a substrate; forming a first circuit layer on at least one surface of the substrate; forming a dielectric layer on the surface of the substrate, and forming a plurality of first and second openings in the dielectric layer, wherein the second openings correspond in position to electrical connection pads of the first circuit layer and expose the electrical connection pads of the first circuit layer; forming a metal layer on the dielectric layer, and allowing the metal layer to fill the first and second openings of the dielectric layer; and removing the metal layer from the dielectric layer except the metal layer disposed in the first and second openings of the dielectric layer, so as to form a second circuit layer embedded in the dielectric layer, wherein the second circuit layer is electrically connected to the first circuit layer by a conductive structure formed in the dielectric layer.

The above fabrication method further comprises the step of forming a conductive layer between the dielectric layer and the metal layer.

In another embodiment of the present invention, the fabrication method may repeat the aforementioned steps to form more dielectric layers and second circuit layers on the above dielectric layer and second circuit layer according to practical electrical design such that a circuit board having multiple circuit layers is fabricated.

The plurality of first and second openings of the dielectric layer are fabricated by the steps of: forming a resist layer on the dielectric layer, and forming a plurality of openings in the resist layer, wherein the openings of the resist layer correspond in position to the electrical connection pads of the first circuit layer and expose a portion of the dielectric layer; removing the resist layer and the exposed portion of the dielectric layer so as to form the first openings in the dielectric layer; and forming the second openings in the first openings corresponding in position to the electrical connection pads of the first circuit layer so as to expose the electrical connection pads of the first circuit layer.

The present invention also discloses a circuit board structure, comprising: a core board having a first circuit layer disposed on at least one surface thereof; a dielectric layer formed on the surface of the core board and formed with a plurality of first and second openings therein, wherein the second openings are formed in the first openings and expose electrical connection pads of the first circuit layer; a second circuit layer formed in the first openings of the dielectric layer; and a conductive structure formed in the second openings of the dielectric layer and electrically connected to the first circuit layer.

The circuit board structure and the method for fabricating the same according to the present invention can enhance the bonding strength between dielectric layers and circuit layers, thereby improving product reliability and quality.

Moreover, in the circuit board structure and the method for fabricating the same according to the present invention, a fine circuit process is not limited by the resolution of the resist layer and the bonding strength between the resist layer and the dielectric layer, such that fine circuit can be formed as desired for use with miniaturized and high-performance electronic products and the thickness of circuits and lines can be effectively controlled.

### BRIEF DESCRIPTION OF THE DRAWINGS

The present invention can be more fully understood by reading the following detailed description of the preferred embodiments, with reference made to the accompanying drawings, wherein:

FIGS. 1A to 1H are cross-sectional views showing a circuit board structure and a method for fabricating the same in accordance with a first preferred embodiment of the present invention;

FIGS. 2A to 2G are cross-sectional views showing a circuit board structure and a method for fabricating the same in accordance with a second preferred embodiment of the present invention;

FIGS. 3A to 3G are cross-sectional views showing a circuit board structure and a method for fabricating the same in accordance with a third preferred embodiment of the present invention; and

FIGS. 4A to 4C are cross-sectional views showing a circuit board structure and a method for fabricating the same in accordance with a fourth preferred embodiment of the present invention.

### DETAILED DESCRIPTION OF THE PREFERRED EMBODIMENTS

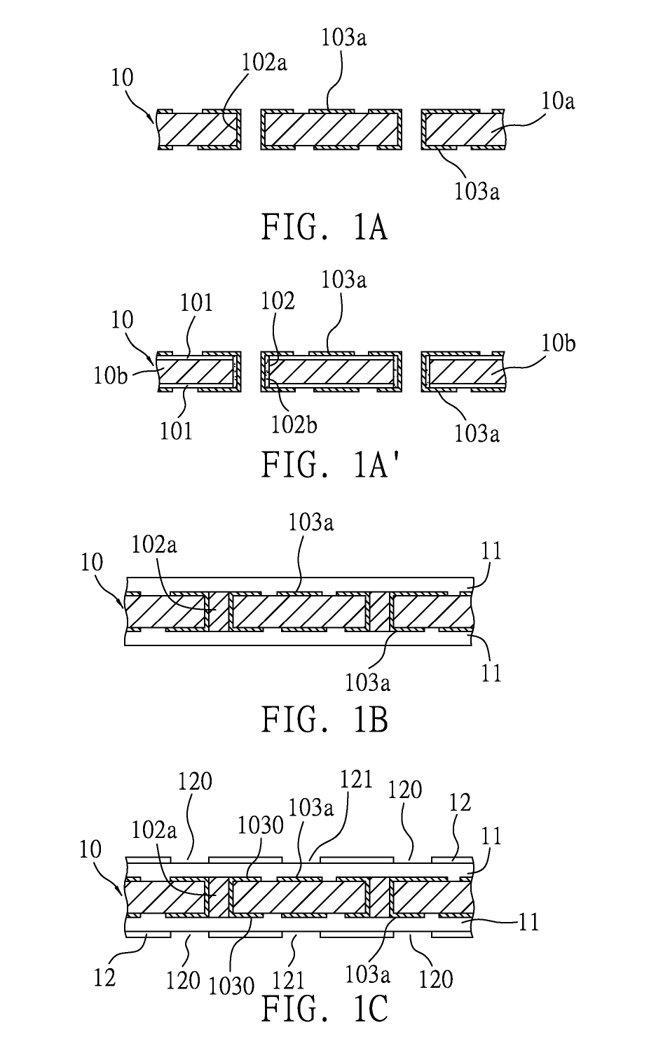

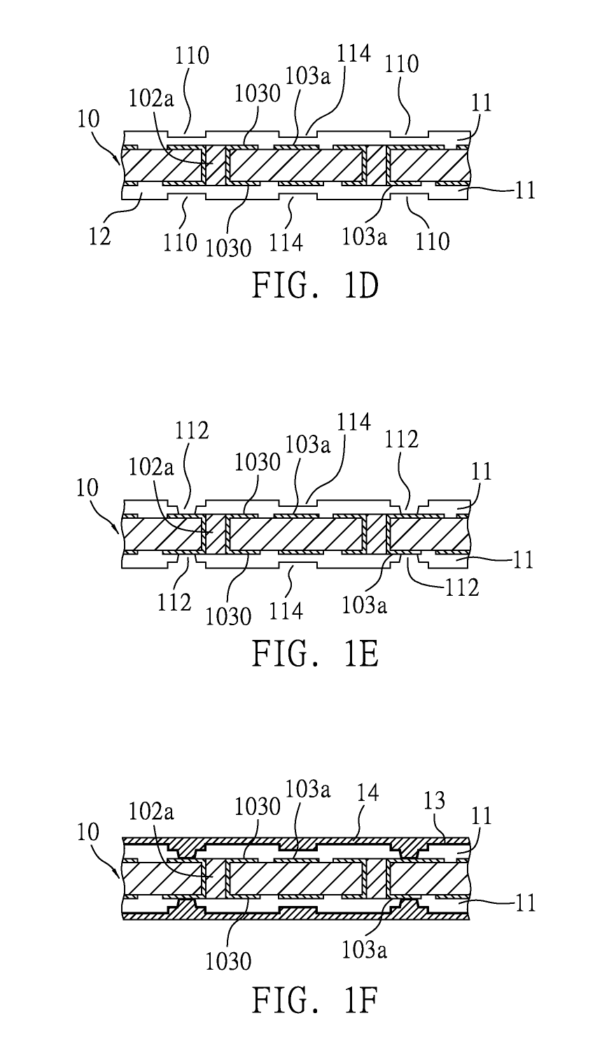

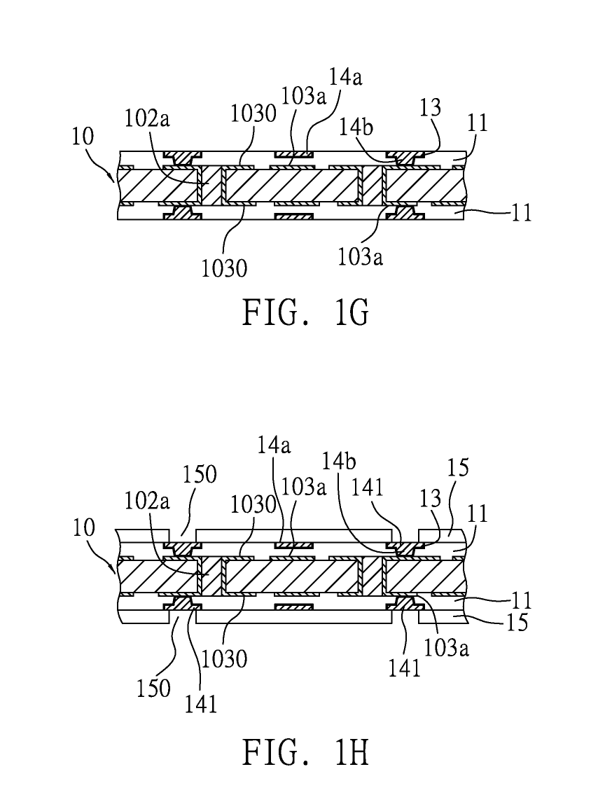

Preferred embodiments of a circuit board structure and a method for fabricating the same as proposed in the present invention are described as follows with reference to FIGS. 1A to 1H, 2A to 2G, 3A to 3G and 4A to 4C. It should be understood that the drawings are simplified schematic diagrams only showing the elements relevant to the present invention, and the layout of elements could be more complicated in practical implementation.

FIGS. 1A to 1H are cross-sectional views showing a circuit board structure and a method for fabricating the same in accordance with a first preferred embodiment of the present invention.

Referring to FIGS. 1A and 1A′, at least one core board 10, 10′ is provided. The core board 10, 10′ can be a single-layer or multi-layer circuit board formed with a first circuit layer on at least one surface thereof. For example, as shown in FIG. 1A, the circuit board comprises a ceramic board 10a as a core thereof, wherein the ceramic board 10a is formed with first circuit layers 103a on upper and lower surfaces thereof and is also formed with at least one plated through holes (PTH) 102a penetrating therethrough to electrically connect the first circuit layers 103a on the upper and lower surfaces of the ceramic board 10a, so as to form a multi-layer circuit board. Alternatively, as shown in FIG. 1A′, the circuit board comprises a metal board 10b as a core thereof, wherein the metal board 10b is formed with dielectric layers 101 on upper and lower surfaces thereof and at least one through hole 102 penetrates through the metal board 10b and the dielectric layers 101. An insulation layer 102b is formed in the through hole 102, and then a plated through hole (PTH) 102a is formed on the insulation layer 102b. A first circuit layer 103a is formed on each of the dielectric layers 101. As a result, a multi-layer circuit board is fabricated as shown in FIG. 1A′. The dielectric layer 101 can be made of epoxy resin, polyimide, cyanate ester, glass fiber, bismaleimide triazine (BT), or FR5 resin composed of a mixture of epoxy resin and glass fiber. The following embodiments are illustrated with a circuit board having the ceramic board 10a as a core thereof and formed with the first circuit layers 103a.

Referring to FIG. 1B, a dielectric layer 11 is formed on each of the first circuit layers 103a provided on the upper and lower surfaces of the core board 10. The dielectric layer 11 is formed by printing, spinning coating or lamination. The dielectric layer 11 can be made of photosensitive or photoinsensitive organic resin, such as Ajinomoto build-up film (ABF), benzocyclobuthene (BCB), liquid crystal polymer (LCP), polyimide (PI), poly(phenylene ether) (PPE), poly(tetrafluoroethylene) (PTFE), FR4, FR5, bismaleimide triazine (BT), or aramide, or a mixture of epoxy resin and glass fiber.

Referring to FIG. 1C, a patterned resist layer 12 is formed on the dielectric layer 11 and covers partially the dielectric layer 11. The resist layer 12 can be a photoresist layer made of such as dry film or liquid photoresist. The resist layer 12 is formed on the dielectric layer 11 by printing, spinning coating, or lamination, and then the resist layer 12 is patterned by exposure and development, so as to form a plurality of openings 120, 121 in the resist layer 12. The openings 120 correspond in position to electrical connection pads 1030 of the first circuit layer 103a. The openings 120, 121 expose a portion of the dielectric layer 11.

Referring to FIG. 1D, the resist layer 12 and the exposed portion of the dielectric layer 11 in the openings 120, 121 of the resist layer 12 are removed by dry etching, such as plasma etching and reactive ionic etching (RIE), so as to form a plurality of first openings 110 in the dielectric layer 11 by removing the portion of the dielectric layer 11 in the openings 120 and form a plurality of third openings 114 in the dielectric layer 11 by removing the portion of the dielectric layer 11 in the openings 121. The first and third openings 110, 114 are in the form of recesses on the surface of the dielectric layer 11, and the first openings 110 do not expose the electrical connection pads 1030 of the first circuit layer 103a. The first and third openings 110, 114 are intended to serve as patterned grooves in the dielectric layer 11 where a second circuit layer can be subsequently fabricated.

The process for removing the resist layer 12 and the portion of the dielectric layer 11 is well known in the art and thus is not further detailed herein.

Referring to FIG. 1E, a plurality of second openings 112 are formed in the first openings 110 of the dielectric layer 11 by laser drilling at positions corresponding to the electrical connection pads 1030 of the first circuit layer 103a, such that the electrical connection pads 1030 are exposed through the second openings 112. The second openings 112 of the dielectric layer 11 are intended for fabricating conductive vias in circuit layers.

Referring to FIG. 1F, a conductive layer 13 (seed layer) is formed on the dielectric layer 11 and in the first, second and third openings 110, 112, 114, and a metal layer 14 is formed on the conductive layer 13 by electroplating, allowing the metal layer 14 to fill the first, second and third openings 110, 112, 114 of the dielectric layer 11. The conductive layer 13 functions as a current conducting path for subsequent metal electroplating. The conductive layer 13 can be made of metal or alloy, or comprises multiple deposited metal layers. For example, the conductive layer 13 is made of copper, tin, nickel, chromium, titanium, copper-chromium alloy, or tin-lead alloy. Alternatively, the conductive layer 13 may be made of a conductive polymer material, such as polyaniline and organosulfide polymer. The conductive layer 13 can be formed by physical vapor deposition (PVD), chemical vapor deposition (CVD), electroless plating, or chemical deposition, such as sputtering, evaporation, arc vapor deposition, ion beam sputtering, laser ablation deposition, plasma-enhanced chemical vapor deposition (PECVD), or electroless plating. The metal layer 14 can be made of lead, tin, silver, copper, gold, bismuth, antimony, zinc, nickel, zirconium, magnesium, indium, tellurium, aluminum, gallium, or an alloy thereof.

Referring to FIG. 1G, for example, a polishing, buffing, or etching process is performed to remove the metal layer 14 from the dielectric layer 11 and remove the conductive layer 13 covered by the metal layer 14, leaving the metal layer 14 in the first, second and third openings 110, 112, 114 of the dielectric layer 11 intact, such that a second circuit layer 14a is formed in the first and third openings 110, 114, and a conductive structure 14b is formed in the second openings 112 and electrically connected to the first circuit layer 103a.

Further, a circuit build-up process may be performed to form more dielectric layers and second circuit layers on the dielectric layer 11 and the second circuit layer 14a so as to form a multi-layer circuit board.

Referring to FIG. 1H, an insulating protection layer 15 is formed on the dielectric layer 11 and the second circuit layer 14a, wherein the insulating protection layer 15 is formed with a plurality of openings 150 for exposing electrical connection pads 141 of the second circuit layer 14a, such fabrication of the circuit board is completed. The insulating protection layer 15 can be a solder mask layer.

Subsequently, conductive elements may be provided on the exposed electrical connection pads 141 of the second circuit layer 14a and are used to mount a semiconductor chip or a printed circuit board (not shown) on the circuit board, thereby accomplishing external electrical connection for the circuit board.

By the aforementioned fabrication method, a circuit board structure is provided in the present invention. The circuit board structure comprises: a core board 10, 10′ having a first circuit layer 103a disposed on at least one surface thereof; a dielectric layer 11 formed on the surface of the core board 10, 10′ and formed with a plurality of first, second and third openings 110, 112, 114 therein, wherein the second openings 112 are formed in the first openings 110 and expose electrical connection pads 1030 of the first circuit layer 103a; a second circuit layer 14a formed in the first and third openings 110, 114 of the dielectric layer 11; and a conductive structure 14b formed in the second openings 112 of the dielectric layer 11 and electrically connected to the first circuit layer 103a. The second circuit layer 14a and the conductive structure 14b are made of lead, tin, silver, copper, gold, bismuth, antimony, zinc, nickel, zirconium, magnesium, indium, tellurium, aluminum, gallium, or an alloy thereof.

The core board 10, 10′ can be a single-layer or multi-layer circuit board formed with a first circuit layer on at least one surface thereof. For example, as shown in FIG. 1A, the circuit board comprises a ceramic board 10a as a core thereof, wherein the ceramic board 10a is formed with first circuit layers 103a on upper and lower surfaces thereof and is also formed with at least one plated through holes (PTH) 102a penetrating therethrough to electrically connect the first circuit layers 103a on the upper and lower surfaces of the ceramic board 10a, so as to form a multi-layer circuit board. Alternatively, as shown in FIG. 1A′, the circuit board comprises a metal board 10b as a core thereof, wherein the metal board 10b is formed with dielectric layers 101 on upper and lower surfaces thereof and at least one through hole 102 penetrates through the metal board 10b and the dielectric layers 101. An insulation layer 102b is formed in the through hole 102, and then a plated through hole (PTH) 102a is formed on the insulation layer 102b. A first circuit layer 103a is formed on each of the dielectric layers 101. As a result, a multi-layer circuit board is fabricated as shown in FIG. 1A′.

The above circuit board structure further comprises a conductive layer 13 disposed between the dielectric layer 11 and the second circuit layer 14a and between the dielectric layer 11 and the conductive structure 14b. On the dielectric layer 11 and the second circuit layer 14a, more dielectric layers and second circuit layers can be formed repeatedly so as to form a circuit board with multiple circuit layers. Further, an insulating protection layer 15 such as a solder mask layer can be applied on the dielectric layer 11 and the second circuit layer 14a, and is formed with openings 150 for exposing electrical connection pads 141 of the second circuit layer 14b.

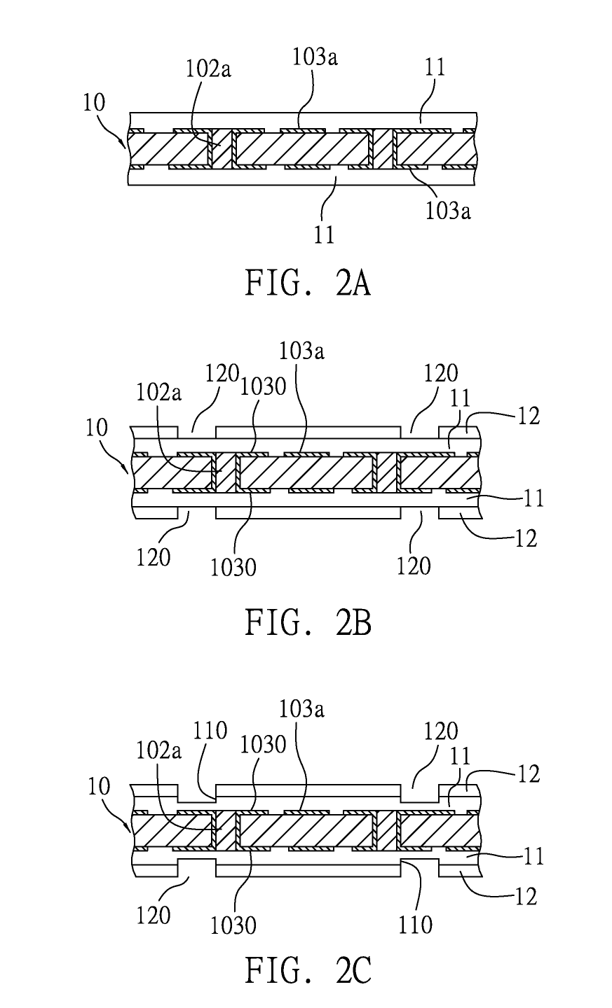

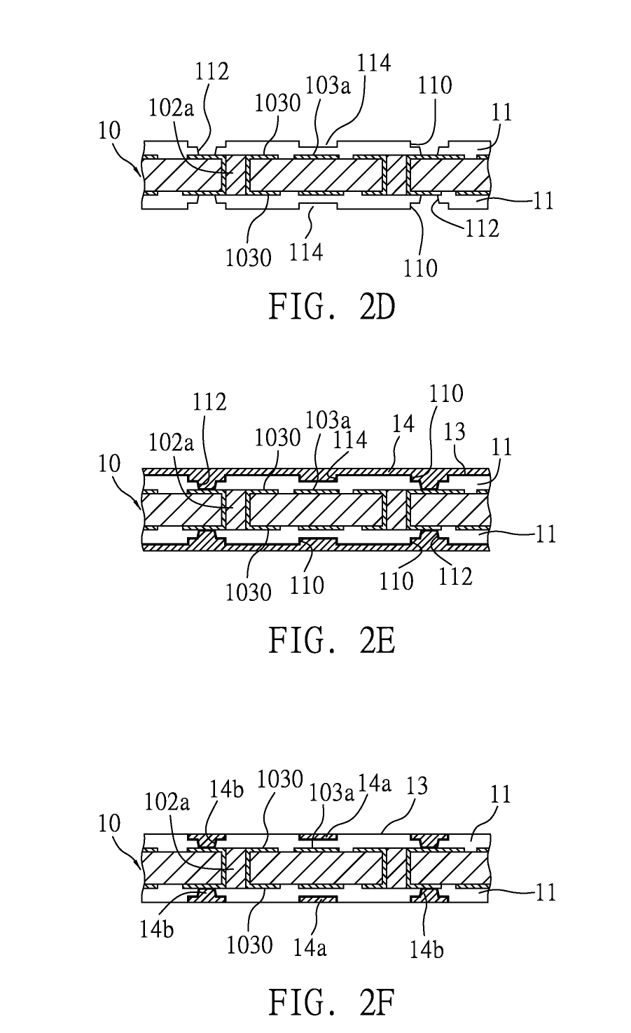

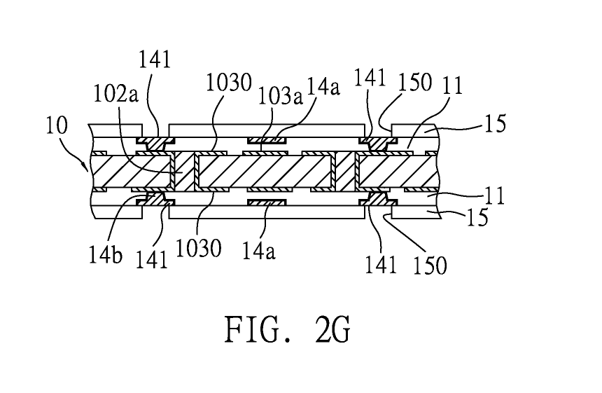

FIGS. 2A to 2G are cross-sectional views showing a circuit board structure and a method for fabricating the same in accordance with a second preferred embodiment of the present invention.

Referring to FIG. 2A, a core board 10 is provided having a first circuit layer 103a formed on each of upper and lower surfaces thereof, wherein a plurality of plated through holes (PTH) 102a are formed through the core board 10 to electrically connect the first circuit layers 103a on the upper and lower surfaces of the core board 10. Then, a dielectric layer 11 is disposed on each of the first circuit layers 103a formed on the upper and lower surfaces of the core board 10.

Referring to FIG. 2B, a patterned resist layer 12 is applied on the dielectric layer 11, and a plurality of openings 120 are formed in the resist layer 12, wherein the openings 120 correspond in position to electrical connection pads 1030 of the first circuit layer 103a and expose a portion of the dielectric layer 11.

Referring to FIG. 2C, a plurality of first openings 110 are formed by laser drilling in the exposed portion of the dielectric layer 11. The first openings 110 are in the form of recesses on the surface of the dielectric layer 11 and do not expose the electrical connection pads 1030 of the first circuit layer 103a.

Referring to FIG. 2D, the resist layer 12 is removed by dry etching, such as plasma etching or reactive ionic etching (RIE), so as to form a plurality of second openings 112 in the first openings 110 of the dielectric layer 11 such that the electrical connection pads 1030 of the first circuit layer 103a are exposed through the second openings 112. Also, the dielectric layer 11 is selectively etched to form a plurality of third openings 114 therein at positions not corresponding to the electrical connection pads 1030 of the first circuit layer 103a. The first and third openings 110, 114 are intended to serve as patterned grooves in the dielectric layer 11 where a second circuit layer can be subsequently fabricated. The second openings 112 are intended for fabricating conductive vias in circuit layers.

Referring to FIG. 2E, a conductive layer 13 is formed on the dielectric layer 11 and in the first, second and third openings 110, 112, 114, and a metal layer 14 is formed on the conductive layer 13 by electroplating, allowing the metal layer 14 to fill the first, second and third openings 110, 112, 114 of the dielectric layer 11. The conductive layer 13 can be made of metal, alloy, or a conductive polymer material.

Referring to FIG. 2F, for example, a buffing or etching process is performed to remove the metal layer 14 from the dielectric layer 11 and remove the conductive layer 13 covered by the metal layer 14, leaving the metal layer 14 in the first, second and third openings 110, 112, 114 of the dielectric layer 11 intact, such that a second circuit layer 14a embedded in the dielectric layer 11 is fabricated and a conductive structure 14b is formed in the second openings 112 to electrically connect the second circuit layer 14a to the first circuit layer 103a.

Further, a circuit build-up process may be performed to form more dielectric layers and second circuit layers on the dielectric layer 11 and the second circuit layer 14a so as to form a multi-layer circuit board.

Referring to FIG. 2G, an insulating protection layer 15 is applied on the dielectric layer 11 and the second circuit layer 14a, and is formed with a plurality of openings 150 for exposing electrical connection pads 141 of the second circuit layer 14a. As a result, fabrication of the circuit board is completed.

Subsequently, conductive elements may be provided on the exposed electrical connection pads 141 of the second circuit layer 14a and are used to mount a semiconductor chip or a printed circuit board (not shown) on the circuit board, thereby accomplishing external electrical connection for the circuit board.

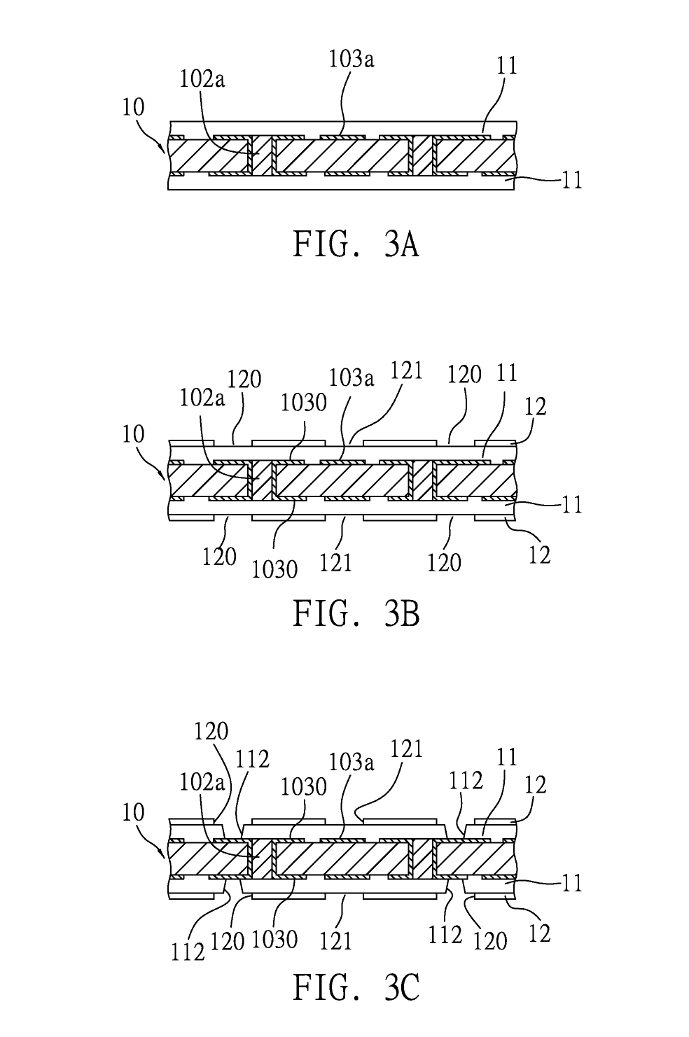

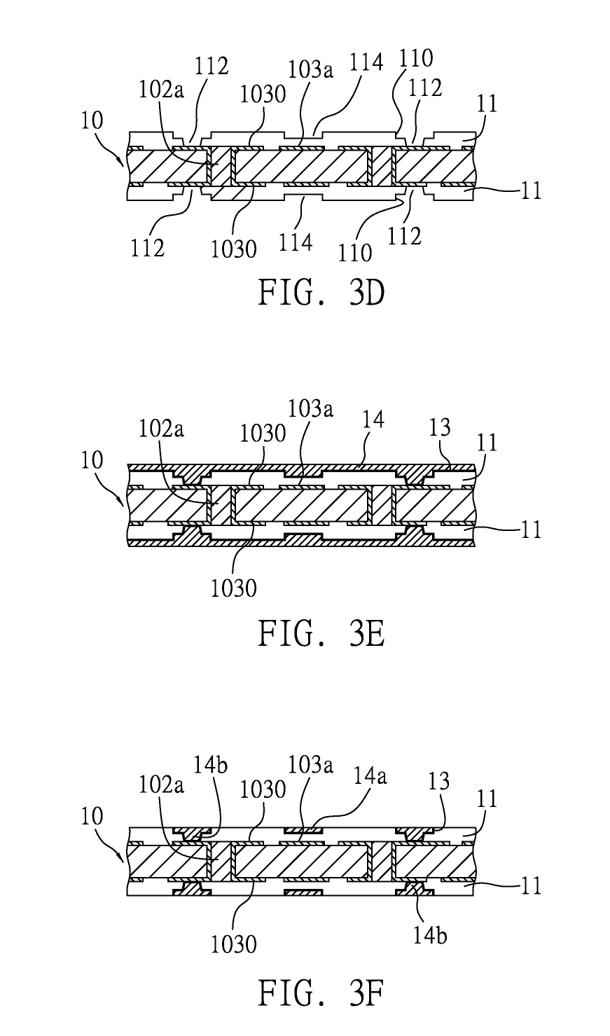

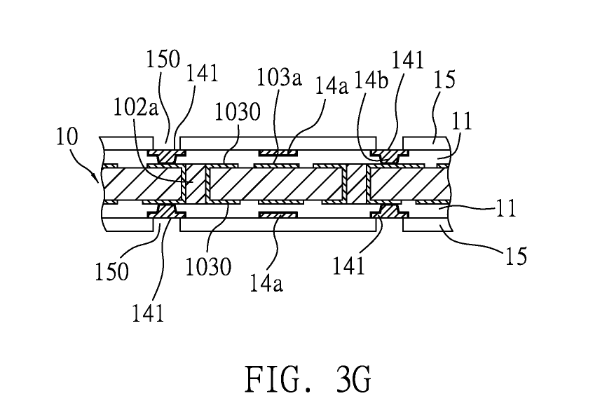

FIGS. 3A to 3H are cross-sectional views showing a circuit board structure and a method for fabricating the same in accordance with a third preferred embodiment of the present invention.

Referring to FIG. 3A, a core board 10 is provided having a first circuit layer 103a formed on each of upper and lower surfaces thereof, wherein a plurality of plated through holes (PTH) 102a are formed through the core board 10 to electrically connect the first circuit layers 103a on the upper and lower surfaces of the core board 10. Then, a dielectric layer 11 is disposed on each of the first circuit layers 103a formed on the upper and lower surfaces of the core board 10.

Referring to FIG. 3B, a patterned resist layer 12 is applied on the dielectric layer 11, and a plurality of openings 120, 121 are formed in the resist layer 12, wherein the openings 120 correspond in position to electrical connection pads 1030 of the first circuit layer 103a, and the openings 120, 121 expose a portion of the dielectric layer 11.

Referring to FIG. 3C, a plurality of second openings 112 are formed by laser drilling in the exposed portion of the dielectric layer 11 in the openings 120 of the resist layer 12. The second openings 112 expose the electrical connection pads 1030 of the first circuit layer 103a. The second openings 112 are intended for fabricating conductive vias in circuit layers.

Referring to FIG. 3D, dry etching, such as plasma etching and reactive ionic etching (RIE), is performed to remove the resist layer 12 and the exposed portion of the dielectric layer 11 in the openings 120, 121 of the resist layer 12, so as to form a plurality of first openings 110 in the dielectric layer 11 at positions corresponding to the openings 120 and form a plurality of third openings 114 in the dielectric layer 11 at positions corresponding to the openings 121. The first and third openings 110, 114 are intended to serve as patterned grooves in the dielectric layer 11 where a second circuit layer can be subsequently fabricated.

Referring to FIG. 3E, a conductive layer 13 is formed on the dielectric layer 11 and in the first, second and third openings 110, 112, 114 and serves as a current conducting path for subsequent electroplating. Then, a metal layer 14 is formed on the conductive layer 13 by electroplating, and fills the first, second and third openings 110, 112, 114 of the dielectric layer 11.

Referring to FIG. 3F, for example, a buffing or etching process is performed to remove the metal layer 14 from the dielectric layer 11 and remove the conductive layer 13 covered by the metal layer 14, leaving the metal layer 14 in the first, second and third openings 110, 112, 114 of the dielectric layer 11 intact, such that a second circuit layer 14a embedded in the dielectric layer 11 is fabricated and a conductive structure 14b is formed in the second openings 112 to electrically connect the second circuit layer 14a to the first circuit layer 103a.

Further, a circuit build-up process may be performed to form more dielectric layers and second circuit layers on the dielectric layer 11 and the second circuit layer 14a so as to form a multi-layer circuit board.

Referring to FIG. 3G, an insulating protection layer 15 is applied on the dielectric layer 11 and the second circuit layer 14a, and is formed with a plurality of openings 150 for exposing electrical connection pads 141 of the second circuit layer 14a. As a result, fabrication of the circuit board is completed.

Subsequently, conductive elements may be provided on the exposed electrical connection pads 141 of the second circuit layer 14a and are used to mount a semiconductor chip or a printed circuit board (not shown) on the circuit board, thereby accomplishing external electrical connection for the circuit board.

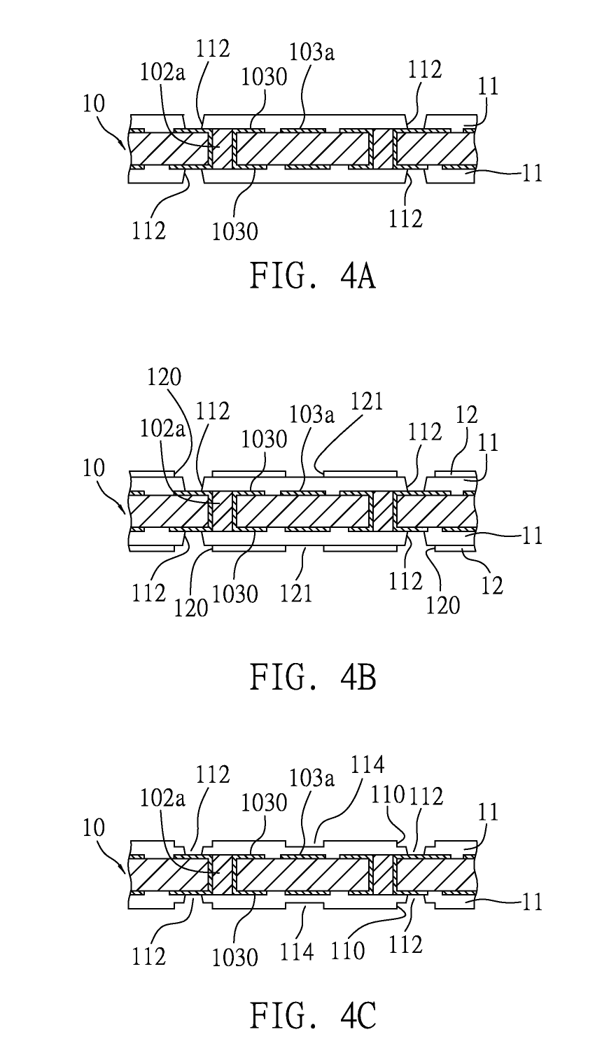

Referring to FIGS. 4A to 4C, in a fourth preferred embodiment of the present invention, the first, second and third openings 110, 112, 114 of the dielectric layer 11 are fabricated by the following steps. First, the second openings 112 are formed in the dielectric layer 11 by laser drilling at positions corresponding to the electrical connection pads 1030 of the first circuit layer 103a, such that the electrical connection pads 1030 of the first circuit layer 103a are exposed through the second openings 112 (as shown in FIG. 4A). Then, the patterned resist layer 12 is applied on the dielectric layer 11 and is formed with a plurality of openings 120, 121 therein, wherein the openings 120 correspond in position to the second openings 112 and the openings 120, 121 expose a portion of the dielectric layer 11 (as shown in FIG. 4B). Subsequently, the resist layer 12 can be removed by dry etching, so as to form the first openings 110 in the dielectric layer 11 at positions corresponding to the second openings 112 and the openings 120 of the resist layer 12 and form the third openings 110 in the dielectric layer 11 at positions corresponding to the openings 121 of the resist layer 12. The first and third openings 110, 114 are intended to serve as patterned grooves in the dielectric layer 11 where the second circuit layer 14a can be subsequently fabricated. The second openings 112 are intended for fabricating conductive vias in circuit layers.

In the present invention, the aforementioned steps may be repeated to form more dielectric layers and second circuit layers on the above dielectric layer 11 and second circuit layer 14a according to practical electrical design such that a circuit board having multiple circuit layers is fabricated.

The circuit board structure formed in the second to fourth embodiments of the present invention is the same as that described in the first embodiment, and thus is not further detailed herein.

Therefore, the method for fabricating a circuit board structure according to the present invention comprises the steps of: providing a substrate; forming a first circuit layer on at least one surface of the substrate; forming a dielectric layer on the surface of the substrate, and forming a plurality of first and second openings in the dielectric layer, wherein the second openings correspond in position to electrical connection pads of the first circuit layer and expose the electrical connection pads of the first circuit layer; forming a metal layer on the dielectric layer, and allowing the metal layer to fill the first and second openings of the dielectric layer; and removing the metal layer from the dielectric layer except the metal layer disposed in the first and second openings of the dielectric layer, so as to form a second circuit layer embedded in the dielectric layer, wherein the second circuit layer is electrically connected to the first circuit layer by a conductive structure formed in the dielectric layer. By the present invention, the bonding strength between a dielectric layer and a circuit layer can be enhanced, such that product reliability and quality are improved.

In the circuit board structure and the method for fabricating the same according to the present invention, a resist layer is provided on a dielectric layer, and a plurality of first and second openings are formed in the dielectric layer by a drilling process and an etching process while the resist layer is removed. Then, a metal layer is formed on the dielectric layer and fills the first and second openings of the dielectric layer. Subsequently, the metal layer is removed from the dielectric layer, leaving the metal layer in the first and second openings of the dielectric layer intact, such that a circuit layer and a conductive structure embedded in the dielectric layer are fabricated.

The circuit board structure of the present invention comprises: a core board having a first circuit layer disposed on at least one surface thereof; a dielectric layer formed on the surface of the core board and formed with a plurality of first and second openings therein, wherein the second openings are formed in the first openings and expose electrical connection pads of the first circuit layer; a second circuit layer formed in the first openings of the dielectric layer; and a conductive structure formed in the second openings of the dielectric layer and electrically connected to the first circuit layer.

Therefore, in the circuit board structure and the method for fabricating the same according to the present invention, a fine circuit process is not limited by the resolution of the resist layer and the bonding strength between the resist layer and the dielectric layer, such that fine circuit can be formed as desired for use with miniaturized and high-performance electronic products and the thickness of circuits and lines can be effectively controlled.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method for fabricating a circuit board structure, comprising:
providing a core board having a first circuit layer disposed on at least one surface thereof;
forming a dielectric layer on the surface of the core board, and forming a plurality of first and second openings in the dielectric layer, wherein the second openings expose electrical connection pads of the first circuit layer;
forming a metal layer on a surface of the dielectric layer and in the first and second openings; and
removing the metal layer from the surface of the dielectric layer, forming a second circuit layer in the first openings, and forming a conductive structure in the second opening, wherein the conductive structure is electrically connected to the first circuit layer.

2. The method of claim 1, wherein the plurality of first and second openings of the dielectric layer are fabricated comprising:
forming a resist layer on the dielectric layer, and forming a plurality of openings in the resist layer, wherein the openings of the resist layer correspond in position to the electrical connection pads of the first circuit layer and expose a portion of the dielectric layer;
removing the resist layer and the exposed portion of the dielectric layer so as to form the plurality of first openings in the dielectric layer; and
forming the plurality of second openings in the first openings of the dielectric layer corresponding in position to the electrical connection pads of the first circuit layer, such that the electrical connection pads of the first circuit layer are exposed through the second openings.

3. The method of claim 2, wherein the second openings are formed by drilling, and dry etching is performed to form the first openings and remove the resist layer.

4. The method of claim 3, wherein the second openings are formed by laser drilling.

5. The method of claim 1, wherein the plurality of first and second openings of the dielectric layer are fabricated by forming a resist layer on the dielectric layer, wherein the resist layer is formed with a plurality of openings therein and a portion of the openings of the resist layer correspond in position to the electrical connection pads of the first circuit layer and expose a portion of the dielectric layer;
forming the plurality of first openings in the exposed portion of the dielectric layer; and
removing the resist layer and the exposed portion of the dielectric layer so as to form the plurality of second openings in the first openings and a plurality of third openings in the dielectric layer and expose the electrical connection pads of the first circuit layer.

6. The method of claim 5, wherein besides the first openings, the second circuit layer is also formed in the third openings.

7. The method of claim 5, wherein the first openings are formed by drilling, and dry etching is performed to form the second openings and the third openings and remove the resist layer.

8. The method of claim 7, wherein the first openings are formed by laser drilling.

9. The method of claim 1, wherein the plurality of first and second openings of the dielectric layer are fabricated by forming a resist layer on the dielectric layer, and forming a plurality of openings in the resist layer, wherein the openings of the resist layer correspond in position to the electrical connection pads of the first circuit layer and expose a portion of the dielectric layer;
forming the plurality of second openings in the exposed portion of the dielectric layer to expose the electrical connection pads of the first circuit layer; and
removing the resist layer and the exposed portion of the dielectric layer so as to form the plurality of first openings in the dielectric layer.

10. The method of claim 9, wherein the second openings are formed by drilling, and dry etching is performed to form the first openings and remove the resist layer.

11. The method of claim 10, wherein the second openings are formed by laser drilling.

12. The method of claim 1, wherein the plurality of first and second openings of the dielectric layer are fabricated comprising:
forming the plurality of second openings in the dielectric layer to expose the electrical connection pads of the first circuit layer;
forming a resist layer on the dielectric layer, and forming a plurality of openings in the resist layer, wherein the openings of the resist layer correspond in position to the second openings and expose a portion of the dielectric layer; and
removing the resist layer and the exposed portion of the dielectric layer so as to form the plurality of first openings in the dielectric layer.

13. The method of claim 12, wherein the second openings are formed by drilling and the first openings are formed by dry etching.

14. The method of claim 13, wherein the second openings are formed by laser drilling.

15. The method of claim 1, further comprising forming a conductive layer between the dielectric layer and the metal layer.

16. The method of claim 1, further comprising forming an insulating protection layer on the dielectric layer and the second circuit layer and formed a plurality of openings in the insulating protection layer to expose electrical connection pads of the second circuit layer.

17. The method of claim 16, wherein the insulating protection layer is a solder mask layer.

18. The method of claim 1, wherein the metal layer is made of one of lead, tin, silver, copper, gold, bismuth, antimony, zinc, nickel, zirconium, magnesium, indium, tellurium, aluminum, gallium, and an alloy thereof.

19. The method of claim 1, further comprising forming at least another dielectric layer and at least one circuit layer on the second circuit layer and the dielectric layer disposed on the surface of the core board such that a circuit board with multiple circuit layers is fabricated.

20. The method of claim 1, wherein the core board is one of a single-layer circuit board and a multi-layer circuit board.

21. The method of claim 20, wherein the circuit board comprises a ceramic board as a core thereof, and the ceramic board is formed with the first circuit layer on each of upper and lower surfaces thereof and is formed with at least one plated through hole (PTH) penetrating therethrough to electrically connect the first circuit layers on the upper and lower surfaces of the ceramic board so as to form a multi-layer circuit board.

22. The method of claim 20, wherein the circuit board comprises a metal board as a core thereof, and the metal board is formed with the dielectric layer on each of upper and lower surfaces thereof and is formed with at least one through hole penetrating through the metal board and the dielectric layers, wherein an insulation layer is formed in the through hole, a plated through hole (PTH) is formed on the insulation layer, and the first circuit layer is formed on each of the dielectric layers, such that a multi-layer circuit board is fabricated.

23. A circuit board structure comprising:
a core board having a first circuit layer disposed on at least one surface thereof;
a dielectric layer formed on the surface of the core board and formed with a plurality of first and second openings therein, wherein the second openings are formed in the first openings and expose electrical connection pads of the first circuit layer;
a second circuit layer formed in the first openings of the dielectric layer; and
a conductive structure formed in the second openings of the dielectric layer and electrically connected to the first circuit layer.

24. The circuit board structure of claim 23, further comprising a conductive layer formed between the dielectric layer and the second circuit layer and between the dielectric layer and the conductive structure.

25. The circuit board structure of claim 23, further comprising an insulating protection layer formed on the dielectric layer and the second circuit layer, wherein the insulating protection layer is formed with openings for exposing electrical connection pads of the second circuit layer.

26. The circuit board structure of claim 25, wherein the insulating protection layer is a solder mask layer.

27. The circuit board structure of claim 23, wherein the second circuit layer and the conductive structure are made of one of lead, tin, silver, copper, gold, bismuth, antimony, zinc, nickel, zirconium, magnesium, indium, tellurium, aluminum, gallium, and an alloy thereof.

28. The circuit board structure of claim 23, further comprising at least another dielectric layer and at least one circuit layer formed on the second circuit layer and the dielectric layer disposed on the surface of the core board so as to form a circuit board with multiple circuit layers.

29. The circuit board structure of claim 23, wherein the core board is one of a single-layer circuit board and a multi-layer circuit board.

30. The circuit board structure of claim 29, wherein the circuit board comprises a ceramic board as a core thereof, and the ceramic board is formed with the first circuit layer on each of upper and lower surfaces thereof and is formed with at least one plated through hole (PTH) penetrating therethrough to electrically connect the first circuit layers on the upper and lower surfaces of the ceramic board so as to form a multi-layer circuit board.

31. The circuit board structure of claim 29, wherein the circuit board comprises a metal board as a core thereof, and the metal board is formed with the dielectric layer on each of upper and lower surfaces thereof and is formed with at least one through hole penetrating through the metal board and the dielectric layers, wherein an insulation layer is formed in the through hole, a plated through hole (PTH) is formed on the insulation layer, and the first circuit layer is formed on each of the dielectric layers, such that a multi-layer circuit board is fabricated.

32. The circuit board structure of claim 29, further comprising a plurality of third openings formed in the dielectric layer, wherein besides the first openings, the second circuit layer is also formed in the third openings.
